(19) United States
(12) Patent Application Publication
(10) Pub. No.: US 2024/0007014 A1
(43) Pub. Date: Jan. 4, 2024

(54) POWER CONVERSION DEVICE

(71) Applicant: FUJI ELECTRIC CO., LTD., Kawasaki-shi (JP)

(72) Inventor: Tomonori KATANO, Matsumoto-city (JP)

(73) Assignee: FUJI ELECTRIC CO., LTD., Kawasaki-shi (JP)

(21) Appl. No.: 18/322,203

(22) Filed: May 23, 2023

(30) Foreign Application Priority Data
Jun. 29, 2022 (JP) 2022-104386

(51) Int. Cl. H02M 7/00; H05K 7/14; H05K 5/02

(52) U.S. Cl. CPC H02M 7/003; H05K 7/1427; H05K 5/0217

(57) ABSTRACT

A power conversion device includes a sealing material that fills the housing space of a case and that has a sealing surface located above a peak point of a wire included in a semiconductor unit in a side view of the device. The power conversion device further includes a buffering member that extends in a predetermined direction in plan view of the device and that has a buffering bottom surface located above the peak point of the wire and under the sealing surface in the side view.

### CROSS-REFERENCE TO RELATED APPLICATION

This application is based upon and claims the benefit of priority of the prior Japanese Patent Application No. 2022-104386, filed on Jun. 29, 2022, the entire contents of which are incorporated herein by reference.

### BACKGROUND OF THE INVENTION

### 1. Field of the Invention

The embodiments discussed herein relate to a power conversion device.

### 2. Background of the Related Art

Semiconductor devices include power devices and are used as power conversion devices. For example, power devices are semiconductor chips such as insulated gate bipolar transistors (IGBTs) and power metal-oxide-semiconductor field-effect transistors (MOSFETs). A power conversion device includes such semiconductor chips and an insulated circuit substrate. The insulated circuit substrate includes an insulating plate and a plurality of wiring boards formed on the front surface of the insulating plate. The semiconductor chips are bonded on the wiring boards. Using a plurality of wires, electrical connections are made between the semiconductor chips and the wiring boards and between the wiring boards in order to form a circuit on the insulated circuit substrate. The plurality of wires include one set of a plurality of wires and another set of a plurality of wires provided in parallel to the one set of wires. This insulated circuit substrate is accommodated in a case, and the case is filled with a sealing material (see, for example, Japanese Laid-open Patent Publication No. 2020-107654).

In such a power conversion device, current flow is controlled using control signals to be given to semiconductor chips. When the power is turned on, current flows not only to the semiconductor chips but also to wires connected to the semiconductor chips, and the wires generate heat, which heats the inside of the power conversion device.

When a semiconductor chip repeatedly generates heat in the above power conversion device, for example, one set of wires connected to the semiconductor chip among the plurality of wires has higher temperature than another set of wires. In this case, a sealing material around the one set of wires repeats expansion and contraction. When the sealing material expands so as to extend outward, the one set of wires stretches and gets closer to the other set of wires. Then, if the one set of wires and the other set of wires that have different electrodes contact each other, insulation breakdown may occur. This causes a failure of the power conversion device, which in turn reduces the reliability of the power conversion device.

### SUMMARY OF THE INVENTION

According to one aspect, there is provided a power conversion device, including: a first conductive unit including a first conductive part having a first front surface and a second conductive part having a second front surface, the second conductive part being separate from the first conductive part in a first direction parallel to the first and second front surfaces; a first wire connecting the first front surface to the second front surface, the first wire extending away from the first front surface and the second front surface and being curved at a first peak point thereof; a second conductive unit located on a side of the first conductive unit, the second conductive unit including a third conductive part having a third front surface, and a fourth conductive part having a fourth front surface, the fourth conductive part being separate from the third conductive part in the first direction; a second wire connecting the third front surface to the fourth front surface, the second wire extending away from the third front surface and the fourth front surface and being curved at a second peak point thereof; a case forming a frame to define a housing space to accommodate therein the first conductive unit and the second conductive unit; a sealing material sealing the housing space and having a sealing surface located above the first peak point and the second peak point; and a buffering member extending in the first direction in a plan view of the power conversion device, the buffering member having a bottom end that, in a side view of the power conversion device, is located above the first peak point and the second peak point and under the sealing surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a sectional view of a power conversion device according to a first embodiment;

FIG. 2 is a plan view of the power conversion device according to the first embodiment;

FIG. 3 is a plan view of a main part (buffering members extending in the ±Y directions) of the power conversion device according to the first embodiment;

FIG. 4 is a first sectional view of the main part (buffering members extending in the ±Y directions) of the power conversion device according to the first embodiment;

FIG. 5 is a second sectional view of the main part (buffering members extending in the ±Y directions) of the power conversion device according to the first embodiment;

FIG. 6 is a plan view of a main part (a buffering member extending in the ±X directions) of the power conversion device according to the first embodiment;

FIG. 7 is a first sectional view of the main part (the buffering member extending in the ±X directions) of the power conversion device according to the first embodiment;

FIG. 8 is a second sectional view of the main part (the buffering member extending in the ±X directions) of the power conversion device according to the first embodiment;

FIG. 9 is a sectional view of a main part of a power conversion device according to a reference example;

FIG. 10 is a sectional view of the main part of the power conversion device (during expansion) according to the reference example;

FIG. 11 is a plan view of the main part of the power conversion device (during expansion) according to the reference example;

FIG. 12 is a sectional view of the main part (buffering members extending in the ±Y directions) of the power conversion device (during expansion) according to the first embodiment;

FIG. 13 is a sectional view of a main part (buffering members extending in the ±Y directions) of a power conversion device (during expansion) according to a second embodiment;

FIG. 14 is a sectional view of a main part (buffering members extending in the ±Y directions) of a power conversion device (during expansion) according to the second embodiment (variation 2-1);

FIG. 15 is a sectional view of a main part (buffering members extending in the ±Y directions) of a power conversion device (during expansion) according to the second embodiment (variation 2-2);

FIG. 16 is a plan view of a power conversion device according to a third embodiment; and

FIG. 17 is a sectional view of a main part (buffering members extending in the ±X directions) of the power conversion device according to the third embodiment.

### DETAILED DESCRIPTION OF THE INVENTION

Hereinafter, embodiments will be described with reference to the accompanying drawings. In the following description, the terms “front surface” and “upper surface” refer to an X-Y surface facing up (in the +Z direction) in a power conversion device 1 of drawings. Similarly, the term “up” refers to an upward direction (the +Z direction) in the power conversion device 1 of the drawings. The terms “rear surface” and “lower surface” refer to an X-Y surface facing down (in the −Z direction) in the power conversion device 1 of the drawings. Similarly, the term “down” refers to a downward direction (the −Z direction) in the power conversion device 1 of the drawings. The same directionality applies to other drawings, as appropriate. The terms “front surface,” “upper surface,” “up,” “above,” “rear surface,” “lower surface,” “down,” and “side surface” are used for convenience to describe relative positional relationships, and do not limit the technical ideas of the embodiments. For example, the terms “up” and “down” are not always related to the vertical directions to the ground. That is, the “up” and “down” directions are not limited to the gravity direction. In addition, in the following description, the term “main component” refers to a component contained at a volume ratio of 80 vol % or more. The expression “being approximately the same” may permit an error range of ±10%. In addition, the expressions “being perpendicular” and “being parallel” may permit an error range of ±10°.

### First Embodiment

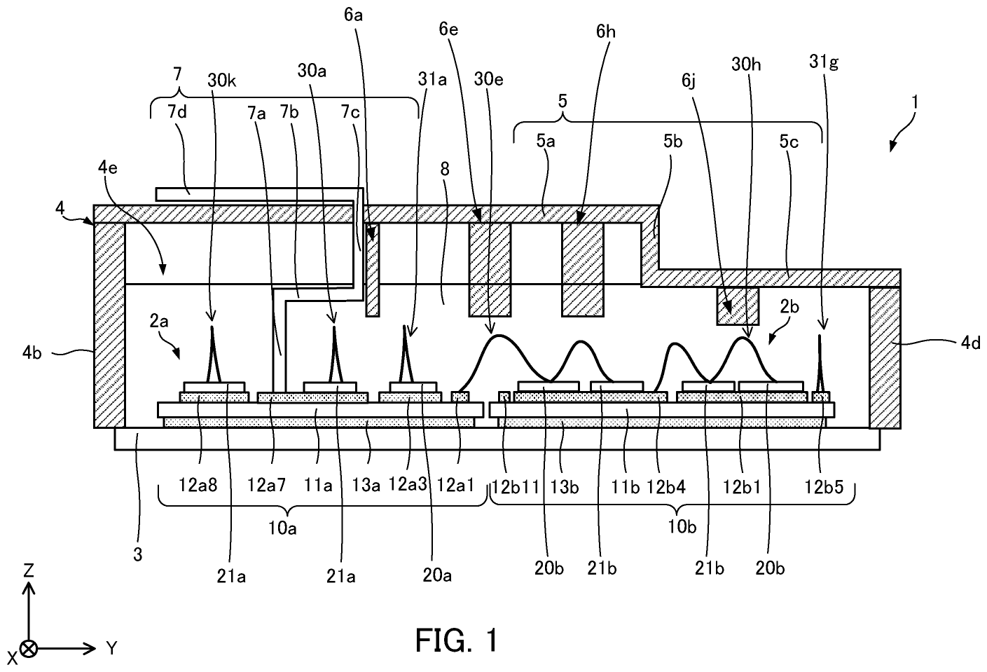

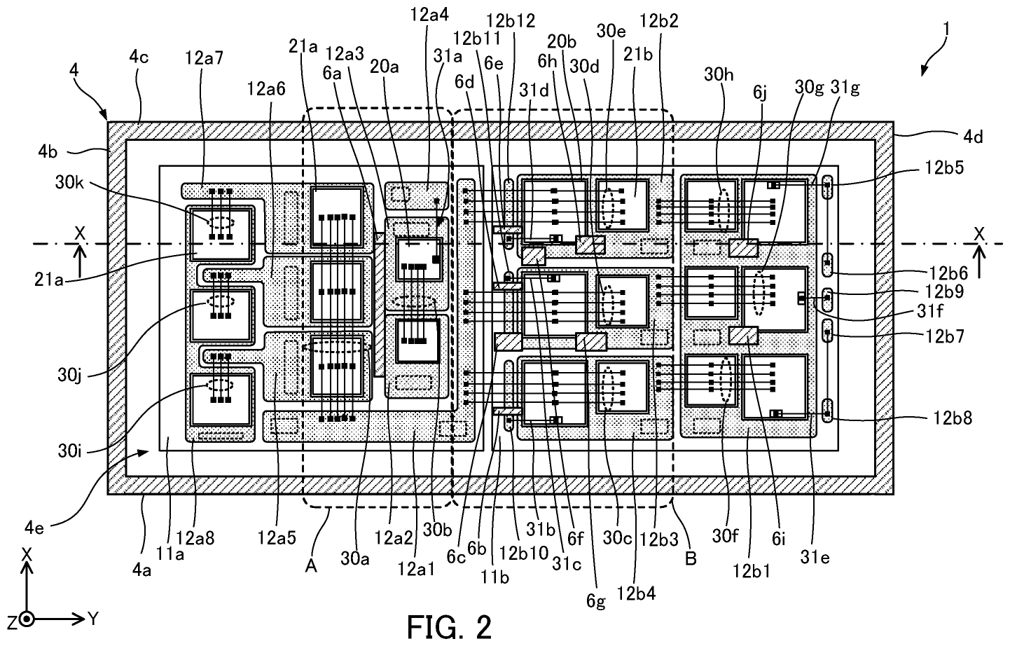

A power conversion device of a first embodiment will be described with reference to FIGS. 1 and 2. FIG. 1 is a sectional view of the power conversion device according to the first embodiment. FIG. 2 is a plan view of the power conversion device according to the first embodiment. In this connection, FIG. 1 is a sectional view taken along a dot-dashed line X-X of FIG. 2. FIG. 2 is a plan view of the power conversion device 1 of FIG. 1 without a lid 5. In addition, the illustration of external connection terminals 7 and a sealing material 8 is omitted in FIG. 2. In this connection, the attachment locations of the external connection terminals 7 and other external connection terminals are represented by broken lines in FIG. 2.

As illustrated in FIGS. 1 and 2, the power conversion device 1 includes semiconductor units 2a and 2b, and a heat dissipation base plate 3 having the semiconductor units 2a and 2b mounted thereon via a solder (not illustrated).

In the power conversion device 1, the semiconductor units 2a and 2b on the heat dissipation base plate 3 are covered by a case 4 and a lid 5. A space (a housing space 4e, which will be described later) surrounded by the case 4 and lid 5 is filled with a sealing material 8. The power conversion device 1 also includes external connection terminals. In this connection, only an external connection terminal 7 among the external connection terminals is illustrated.

The heat dissipation base plate 3 is rectangular in plan view. The semiconductor units 2a and 2b (insulated circuit substrates 10a and 10b), which will be described later, are disposed side by side on the heat dissipation base plate 3. In addition, the case 4, which will be described later, is attached to the outer periphery of the heat dissipation base plate 3 outside a region thereof where the insulated circuit substrates and 10b are disposed. In addition, the corners of the heat dissipation base plate 3 may be rounded or chamfered. The heat dissipation base plate 3 is made of a metal with high thermal conductivity as a main component. Examples of the metal here include copper, aluminum, and an alloy containing at least one of these. Plating may be performed to improve the corrosion resistance of the heat dissipation base plate 3. Examples of the plating material used here include nickel, a nickel-phosphorus alloy, and a nickel-boron alloy.

A cooling unit may be attached to the rear surface of the heat dissipation base plate 3 using a bonding material. As the cooling unit, a heat sink with a plurality of fins or a cooling device using cold water may be used, for example. The heat sink is made of a material with high thermal conductivity, such as aluminum, iron, silver, copper, or an alloy containing at least one of these, as with the heat dissipation base plate 3. Plating may be performed to improve the corrosion resistance of the heat sink as well. Examples of the plating material used here include nickel, a nickel-phosphorus alloy, and a nickel-boron alloy. A plurality of fins may be provided directly on the rear surface of the heat dissipation base plate 3.

In addition, the bonding material used here is solder, a brazing material, or a sintered metal. As the solder, lead-free solder is used. The lead-free solder contains, as a main component, an alloy containing at least two of tin, silver, copper, zinc, antimony, indium, and bismuth, for example. The solder may also contain an additive. Examples of the additive include nickel, germanium, cobalt, and silicon. The solder containing the additive exhibits improved wettability, gloss, and bonding strength, which results in improving the reliability. The brazing material contains, as a main component, at least one of an aluminum alloy, a titanium alloy, a magnesium alloy, a zirconium alloy, and a silicon alloy, for example. The cooling unit may be bonded by brazing using the above bonding material. The sintered metal contains silver or a silver alloy as a main component, for example.

Alternatively, the bonding material may be a thermal interface material. For example, the thermal interface material is an elastomer sheet, a room temperature vulcanization (RTV) rubber, a gel, a phase change material, or a material containing one of these. The use of such a brazing material or thermal interface material for the attachment of the cooling unit improves the heat dissipation of the power conversion device 1.

The case 4 is rectangular in plan view. The case 4 has a rectangular shape in side view from the Y direction, and has a stepped L-shape in side view from the X direction. The stepped L-shape here is a rectangular shape with a cutout in the top side thereof. The case 4 has a long sidewall 4a, short sidewall 4b, long sidewall 4c, and short sidewall 4d that surround the four sides of the housing space 4e in order in plan view. The long sidewalls 4a and 4c is parallel to the Z-Y plane and correspond to the long side of the case 4. Each long sidewall 4a and 4c is higher by the height of a step member 5b in a region corresponding to a high lid member 5a than in a region corresponding to a low lid member 5c. These step member 5b, high lid member 5a, and low lid member 5c will be described later. The short sidewalls 4b and 4d are parallel to the Z-X plane and correspond to the short side of the case 4. The short sidewall 4b is higher (in the +Z direction) by the height of the step member 5b than the short sidewall 4d. The bottoms of these long sidewalls 4a and 4c and short sidewalls 4b and 4d are adhered to the outer periphery of the heat dissipation base plate 3 using an adhesive (not illustrated).

The external connection terminals 7 may be integrally formed with the lid 5. The lid 5 is rectangular in plan view. The lid 5 covers a rectangular opening surrounded by the long sidewalls 4a and 4c and short sidewalls 4b and 4d in plan view. The lid 5 includes the high lid member 5a, step member 5b, and low lid member 5c. In plan view, the high lid member 5a is rectangular, and covers two-thirds in the −Y direction of the opening surrounded by the long sidewalls 4a and 4c and short sidewalls 4b and 4d. The high lid member 5a is located higher than the low lid member 5c in side view. In addition, an external connection portion 7d of an external connection terminal 7 is exposed on the front surface of the high lid member 5a. In plan view, the low lid member 5c is rectangular, and covers one-third in the +Y direction of the opening surrounded by the long sidewalls 4a and 4c and short sidewalls 4b and 4d. The step member 5b connects the high lid member 5a and the low lid member 5c. With the step member 5b, the high lid member 5a and the low lid member 5c form a step. The height (the length in the +Z direction) of the step member is set such that the height measured from the heat dissipation base plate 3 to the high lid member 5a is at least 120% but 250% or less of the height measured from the heat dissipation base plate 3 to the low lid member 5c. In this connection, the areas of the high lid member 5a and the low lid member 5c in plan view have been described above as an example. In addition, the heights of the long sidewalls 4a and 4c and short sidewalls 4b and 4d have been described above as an example. For example, the long sidewalls 4a and 4c and short sidewalls 4b and 4d may have the same height. In this case, the lid 5 does not include the step member 5b, but has a flat plate shape.

In addition, buffering members 6a to 6j are formed on the rear surfaces of the high lid member 5a and low lid member of the lid 5. The buffering members 6a to 6j may be referred to as buffering members 6 without distinction among them. The buffering member 6a is formed in the ±X directions (in parallel to the short sidewalls 4b and 4d) on the rear surface of the high lid member 5a. The buffering members 6b to 6h are formed in the ±Y directions (in parallel to the long sidewalls 4a and 4c) on the rear surface of the high lid member 5a. The buffering members 6i and 6j are formed in the ±Y directions (in parallel to the long sidewalls 4a and 4c) on the rear surface of the low lid member 5c.

The buffering members 6a to 6j each extend from the rear surface of the high lid member 5a or low lid member 5c toward the heat dissipation base plate 3. In addition, the buffering member 6a is provided between wires 30a and wires 30b in plan view. The buffering member 6b is provided between a wire 31b and wires 30c in plan view. The buffering members 6c and 6g are provided between the wires 30c and wires 30d in plan view. The buffering member 6d is provided between a wire 31c and the wires 30d in plan view. The buffering member 6e is provided between a wire 31d and wires 30e in plan view. The buffering member 6f is provided between the wire 31d and the wire 31c in plan view. The buffering member 6h is provided between the wires 30d and the wires 30e in plan view. The buffering member 6i is provided between wires 30f and wires 30g in plan view. The buffering member 6j is provided between the wires 30g and wires 30h in plan view. The buffering members 6a to 6j will be described in detail later.

As described earlier, the external connection terminals 7 are bonded respectively to the dotted rectangular areas on the wiring boards illustrated in FIG. 2. The external connection terminals 7 bonded to the wiring boards 12a5, 12a6, and 12a7, which will be described later, will now be described. The external connection terminals 7 are made of a metal with high electrical conductivity as a main component. Examples of the metal include copper and a copper alloy. Plating may be performed on the external connection terminals 7. Examples of the plating material used here include nickel, a nickel-phosphorus alloy, a nickel-boron alloy, silver, and a silver alloy. The external connection terminals 7 subjected to the plating achieve improved corrosion resistance and bonding property. Each external connection terminal 7 is formed of a planar member, and has an equal thickness in its entirety.

Each external connection terminal 7 includes a leg portion 7a, a parallel linking portion 7b, a vertical linking portion 7c, and the external connection portion 7d. The leg portion 7a of the external connection terminal 7 is connected to the insulated circuit substrate 10a, and the external connection portion 7d thereof is connected to an external device. The leg portion 7a has a flat plate shape, has a bottom end bonded to a wiring board using a bonding member, and extends vertically upward (in the +Z direction) with respect to the front surface of the wiring board. Not only the bonding member but also ultrasonic bonding may be used to bond the leg portion 7a. The height (in the +Z direction) of the leg portion 7a is greater than the heights measured from the front surfaces of the wiring boards 12a5, 12a6, and 12a7 to the highest point of the wires and is less than the height of the lid 5. The width (in the X direction) of the leg portion 7a is approximately equal to one side of the semiconductor chip 21a, which will be described later. The parallel linking portion 7b has a flat plate shape. The parallel linking portion 7b has one end connected to the top end of the leg portion 7a and has the other end extending toward the short sidewall 4d in parallel to the long sidewalls 4a and 4c above the wires 30a. The other end of the parallel linking portion 7b extends up to above the wires 30a. The width (in the X direction) of the parallel linking portion 7b may be set such that the parallel linking portion 7b is placed over the connection points of the wires 30a to the semiconductor chip 21a and such that the parallel linking portion 7b and its adjacent parallel linking portion 7b have a space therebetween to maintain insulation property.

The vertical linking portion 7c has a flat plate shape. The vertical linking portion 7c has one end connected to the other end of the parallel linking portion 7b and has the other end extending vertically (in the +Z direction) to the parallel linking portion 7b. The other end of the vertical linking portion 7c extends and projects from the lid 5. The width (in the X direction) of the vertical linking portion 7c may be approximately the same as that of the parallel linking portion 7b.

The external connection portion 7d has a flat plate shape. The external connection portion 7d has one end connected to the other end of the vertical linking portion 7c projecting from the lid 5, and has the other end extending toward the short sidewall 4b (in the −Y direction) over the lid 5. The other end of the external connection portion 7d extends but does not project from the lid 5. The width (in the X direction) of the external connection portion 7d may be approximately the same as the widths of the vertical linking portion 7c and parallel linking portion 7b.

The above case 4 and the lid 5 that is formed with the buffering members 6a to 6j are each formed of a thermoplastic resin. Examples of the thermoplastic resin here include a PPS resin, PBT resin, PBS resin, PA resin, and ABS resin.

In addition, for the sealing material 8, a silicone gel is used, for example. The silicone gel exhibits high adhesion, and is unlikely to be peeled off even when temperature changes occur in the use environment. In addition, insulation breakdown is unlikely to occur at a sealing surface 8a. The sealing material 8 fills the housing space 4e of the case 4 up to seal at least the below-described wires entirely.

The semiconductor unit 2a includes the insulated circuit substrate 10a and semiconductor chips 20a and 21a disposed on the insulated circuit substrate 10a. The semiconductor unit 2b includes the insulated circuit substrate and semiconductor chips 20b and 21b disposed on the insulated circuit substrate 10b. In addition, the semiconductor units 2a and 2b include the wires 30a to 30k and 31a to 31g. The wires to 30k and 31a to 31g mechanically and electrically connect between the semiconductor chips 20a, 21a, 20b, and 21b and between the semiconductor chips 20a, 21a, 20b, and 21b and the insulated circuit substrates 10a and 10b.

The insulated circuit substrate 10a includes an insulating plate 11a, wiring boards 12a1 to 12a8 provided on the front surface of the insulating plate 11a, and a metal plate 13a provided on the rear surface of the insulating plate 11a. The insulated circuit substrate 10b includes an insulating plate 11b, wiring boards 12b1 to 12b12 provided on the front surface of the insulating plate 11b, and a metal plate 13b provided on the rear surface of the insulating plate 11b. The insulating plates 11a and 11b and metal plates 13a and 13b are rectangular in plan view. In addition, the corners of the insulating plates 11a and 11b and metal plates 13a and 13b may be rounded or chamfered. In plan view, the metal plates 13a and 13b are smaller in size than the insulating plates 11a and 11b and are formed inside the insulating plates 11a and 11b, respectively.

The insulating plates 11a and 11b have insulation property and are made of a material with high thermal conductivity as a main component. Examples of the material here include a ceramic material or an insulating resin. Examples of the ceramic material here include aluminum oxide, aluminum nitride, and silicon nitride. Examples of the insulating resin include a paper phenolic board, a paper epoxy board, a glass composite board, and a glass epoxy board.

The wiring boards 12a1 to 12a8 and 12b1 to 12b12 are conductive parts that are made of a metal with high electrical conductivity as a main component. Examples of the metal here include copper, aluminum, and an alloy containing at least one of these. In addition, plating may be performed on the surfaces of the wiring boards 12a1 to 12a8 and 12b1 to 12b12 to improve their corrosion resistance. Examples of the plating material here include nickel, a nickel-phosphorus alloy, and a nickel-boron alloy. In this connection, the wiring boards 12a1 to 12a8 and 12b1 to 12b12 are illustrated as an example in FIG. 2. The quantity, shapes, sizes, and others of the wiring boards 12a1 to 12a8 and 12b1 to 12b12 may be appropriately selected according to necessity.

The metal plates 13a and 13b are smaller in area than the insulating plates 11a and 11b, respectively, are larger in area than a region where the wiring boards 12a1 to 12a8 are formed and a region where the wiring boards 12b1 to 12b12 are formed, respectively, and are rectangular as with the insulating plates 11a and 11b. In addition, the corners of the metal plates 13a and 13b may be rounded or chamfered. The metal plates 13a and 13b are formed on the entire surfaces of the insulating plates 11a and 11b except the edge portions thereof, respectively. The metal plates 13a and 13b are made of a metal with high thermal conductivity as a main component. Examples of the metal include copper, aluminum, and an alloy containing at least one of these. In addition, plating may be performed on the metal plates 13a and 13b to improve their corrosion resistance. Examples of the plating material here include nickel, a nickel-phosphorus alloy, and a nickel-boron alloy.

As the insulated circuit substrates 10a and 10b configured as above, a direct copper bonding (DCB) substrate, an active metal brazed (AMB) substrate, or a resin insulating substrate may be used, for example.

The semiconductor chips 20a, 21a, 20b, and 21b include power device elements that are made of silicon, silicon carbide, or gallium nitride. A power device element is a switching element or a diode element. The semiconductor chips and 20b include switching elements. A switching element is an IGBT or a power MOSFET, for example.

In the case where a semiconductor chip 20a, 20b includes an IGBT, the semiconductor chip 20a, 20b has a collector electrode serving as a main electrode on the rear surface thereof, and has a gate electrode serving as a control electrode and an emitter electrode serving as a main electrode on the front surface thereof. In the case where a semiconductor chip 20a, 20b includes a power MOSFET, the semiconductor chip 20a, 20b has a drain electrode serving as a main electrode on the rear surface thereof, and has a gate electrode serving as a control electrode and a source electrode serving as a main electrode on the front surface thereof. That is, the main electrodes and control electrodes on the front surfaces of the semiconductor chips 20a and 20b and the main electrodes on the rear surfaces thereof are conductive parts.

The semiconductor chips 21a and 21b include diode elements. A diode element is a free wheeling diode (FWD) such as a Schottky barrier diode (SBD) or a P-intrinsic-N (PiN) diode. The semiconductor chip 21a, 21b of this type has a cathode electrode serving as a main electrode on the rear surface thereof and has an anode electrode serving as a main electrode on the front surface thereof. That is, the main electrodes on the front and rear surfaces of the semiconductor chips 21a and 21b are conductive parts.

The rear surface of the semiconductor chip 20a is mechanically and electrically bonded to the wiring board 12a3 using a bonding material (not illustrated). The rear surfaces of the semiconductor chips 21a are mechanically and electrically bonded to the wiring boards 12a2 and 12a5 to 12a8 using the bonding member (not illustrated). The rear surfaces of the semiconductor chips 20b and 21b are mechanically and electrically bonded to the wiring boards 12b1 to 12b4 using the bonding member (not illustrated). In this connection, in place of the semiconductor chips 20a, 21a, 20b, and 21b, reverse-conducting (RC)-IGBTs may be used. An RC-IGBT has the functions of both an IGBT and an FWD.

In this connection, two of the semiconductor chips 20a, 21a, 20b, and 21b are separate from each other in a predetermined direction and are connected with a wire (reference numeral omitted), and a semiconductor chip 20a, 21a, 20b, or 21b and a wiring board (reference numeral omitted) are separate from each other in a predetermined direction and are connected with a wire (reference numeral omitted) that will be described later. Here, the predetermined directions in which the two of the semiconductor chips 20a, 21a, 20b, and 21b are separate from each other and in which the semiconductor chip 20a, 21a, 20b, or 21b and the wiring board (reference numeral omitted) are separate from each other are each referred to as a first direction.

More specifically, two conductive parts are separate from each other in a predetermined direction, and are connected with a wire (reference numeral omitted) that will be described later. The predetermined direction in which the two conductive parts are separate from each other is referred to as the first direction. Conductive parts include the main electrodes on the front surfaces of the semiconductor chips 20a, 21a, 20b, and 21b and the wiring boards (reference numerals omitted) illustrated in FIG. 2. Examples of such two conductive parts in FIG. 2 are: the main electrodes of semiconductor chips 20a and 21a; the main electrodes of two semiconductor chips 21a; the main electrode of a semiconductor chip 21a and a wiring board (reference numeral omitted); the main electrode of a semiconductor chip 20b and a wiring board (reference numeral omitted); the main electrodes of semiconductor chips 20b and 21b; and the main electrode of a semiconductor chip 21b and a wiring board (reference numeral omitted). The first direction is either the X direction or the Y direction depending on the locations of conductive parts connected with a wire. For example, referring to FIG. 2, the first direction with respect to the semiconductor chips 21a and wiring board 12a1 connected with the wires 30a is the ±X directions. The first direction with respect to the semiconductor chips 20a and 21a connected with the wires 30b is also the ±X directions. In addition, the first direction with respect to the semiconductor chips 20b and 21b and wiring board 12a1 connected with the wires 30d is the ±Y directions.

The bonding material is solder or a sintered metal. A lead-free solder is used as the solder. For example, the lead-free solder contains, as a main component, an alloy containing at least two of tin, silver, copper, zinc, antimony, indium, and bismuth. In addition, the solder may contain an additive. Examples of the additive include nickel, germanium, cobalt, and silicon. The solder containing the additive exhibits improved wettability, gloss, and bonding strength, which results in improving the reliability. Examples of a metal used for the sintered metal include silver and a silver alloy.

The wires 30a to 30k and 31a to 31g each connect between the main electrodes on the front surfaces of two of the semiconductor chips 20a, 20b, 21a, and 21b separate from each other in the first direction, between the main electrode on the front surface of one of the semiconductor chips 20a, 20b, 21a, and 21b and the front surface of one wiring board (reference numeral omitted), or between the front surfaces of wiring boards (reference numerals omitted), as appropriate according to necessity (such two conductive parts connected with a wire are collectively referred to as a conductive unit). These wires 30a to 30k and 31a to 31g are made of a metal with high electrical conductivity as a main component. Examples of the metal include aluminum, copper, and an alloy containing at least one of these.

The wires 30a mechanically and electrically connect the wiring board 12a1 and the main electrodes of three semiconductor chips 21a, which are conductive parts. In this connection, the wiring board 12a1 has a portion that is located apart in the −X direction from the main electrode of the semiconductor chip 21a closest to the long sidewall 4a among the semiconductor chips 21a arranged in a line.

The wires 30b mechanically and electrically connect the main electrode of a semiconductor chip 20a and the main electrode of a semiconductor chip 21a, which are conductive parts. In this connection, the main electrode of the semiconductor chip and the main electrode of the semiconductor chip 21a are separate from each other in the ±X directions.

The wires 30c to 30e each mechanically and electrically connect the main electrode of a semiconductor chip 21b, the main electrode of a semiconductor chip 20b, and the wiring board 12a1, which are conductive parts. In this connection, the wiring board 12a1 has a portion that is located apart in the −Y direction from the main electrodes of the semiconductor chips 20b arranged in a line.

The wires 30f mechanically and electrically connect the main electrode of a semiconductor chip 21b, the main electrode of a semiconductor chip 20b, and the wiring board 12b4, which are conductive parts. In this connection, the wiring board 12b4 has a portion that is located apart from the main electrode of the semiconductor chip 21b in the −Y direction.

The wires 30g mechanically and electrically connect the main electrode of a semiconductor chip 21b, the main electrode of a semiconductor chip 20b, and the wiring board 12b3, which are conductive parts. In this connection, the wiring board 12b3 has a portion that is located apart from the main electrode of the semiconductor chip 21b in the −Y direction.

The wires 30h mechanically and electrically connect the main electrode of a semiconductor chip 21b, the main electrode of a semiconductor chip 20b, and the wiring board 12b2, which are conductive parts. In this connection, the wiring board 12b2 has a portion that is located apart from the main electrode of the semiconductor chip 21b in the −Y direction.

The wires 30i mechanically and electrically connect the wiring board 12a5 and the main electrode of a semiconductor chip 21a, which are conductive parts. In this connection, the wiring board 12a5 has a portion that is located apart from the main electrode of the semiconductor chip 21a in the +X direction.

The wires 30j mechanically and electrically connect the wiring board 12a6 and the main electrode of a semiconductor chip 21a, which are conductive parts. In this connection, the wiring board 12a6 has a portion that is located apart from the main electrode of the semiconductor chip 21a in the +X direction.

The wires 30k mechanically and electrically connect the wiring board 12a7 and the main electrode of a semiconductor chip 21a, which are conductive parts. In this connection, the wiring board 12a7 has a portion that is located apart from the main electrode of the semiconductor chip 21a in the +X direction.

In this connection, the wires 30a and 30b are parallel to each other. The wires 30c to 30e are parallel to each other. More specifically, the wires 30c to 30e are arranged to face each other such that their peak points are aligned (in the ±X directions) and their connection points are aligned (in the ±X directions). The wires 30f to 30h are parallel to each other. More specifically, the wires 30f to 30h are arranged to face each other such that their peak points are aligned (in the ±X directions) and their connection points are aligned (in the ±X directions).

The wire 31a mechanically and electrically connects the control electrode of a semiconductor chip 20a and the wiring board 12a4. In this connection, the wiring board 12a4 is separate from the control electrode of the semiconductor chip in the +X direction.

The wires 31b to 31d each mechanically and electrically connect the control electrode of a semiconductor chip 20b and one of the wiring boards 12b10 to 12b12. In this connection, the wiring boards 12b10 to 12b12 are respectively separate from the control electrodes of the corresponding semiconductor chips 20b in the −Y direction.

The wire 31e mechanically and electrically connects the control electrode of a semiconductor chip 20b and the wiring boards 12b8 and 12b7. The wire 31f mechanically and electrically connects the control electrode of a semiconductor chip 20b and the wiring board 12b9. The wire 31g mechanically and electrically connects the control electrode of a semiconductor chip 20b and the wiring boards 12b5 and 12b6. In this connection, the wiring boards 12b5 to 12b9 are separate from the control electrodes of the corresponding semiconductor chips 20b in the +Y direction.

In this connection, the wires 30a, 30b, 30i to 30k, and 31a each extend in the direction from the long sidewall 4a toward the long sidewall 4c. More specifically, the wires 30a, 30i to 30k, and 31a may be arranged in parallel to the X direction (the short sidewalls 4b and 4d) corresponding to the short side of the power conversion device 1 in plan view.

In addition, the wires 30c to 30h and 31b to 31g each extend in the direction from the short sidewall 4b toward the short sidewall 4d. More specifically, the wires 30c to 30h and 31b to 31g may be arranged in parallel to the Y direction (the long sidewalls 4a and 4c) corresponding to the long side of the power conversion device 1 in plan view.

In addition, the wires 30a to 30k and 31a to 31g each have an arched shape in which they extend away from the front surfaces of the corresponding insulated circuit substrates 10a and 10b and are curved at their peak points, in order to connect connection targets. The shapes of the wires 30a to 30k and 31a to 31g are not limited to this, but may be such that they extend obliquely upward from the front surfaces of the corresponding insulated circuit substrates 10a and 10b and then are flat at their top portions. For example, the wires 30a to 30k and 31a to 31g may be provided in a trapezoid shape. In the case of the trapezoid shape, the flat portion of each wire 30a to 30k and 31a to 31g approximately parallel to the front surfaces of the insulated circuit substrates 10a and 10b may be taken as corresponding to the peak point of the arched shape.

The power conversion device 1 configured as above is manufactured in the following manner. First, the semiconductor units 2a and 2b are bonded to the front surface of the heat dissipation base plate 3 using a bonding member. Then, the semiconductor units 2a and 2b are wired using the wires 30a to 30k and 31a to 31g. In addition, the external connection terminals 7 and other external connection terminals are bonded to the semiconductor units 2a and 2b. The bottom ends of the long sidewall 4a, short sidewall 4b, long sidewall 4c, and short sidewall 4d of the case 4 are bonded to the outer periphery of the heat dissipation base plate 3 using an adhesive.

The housing space 4e surrounded by the heat dissipation base plate 3 and case 4 is filled with the sealing material 8. The sealing material 8 fills the housing space 4e up to seal at least the wires 30a to 30k and 31a to 31g. Before the sealing material 8 is cured, the lid 5 with the buffering members 6 is attached to the case 4. By doing so, the buffering members 6 enter the sealing material 8. The sealing material 8 is cured thereafter, thereby obtaining the power conversion device 1 illustrated in FIGS. 1 and 2.

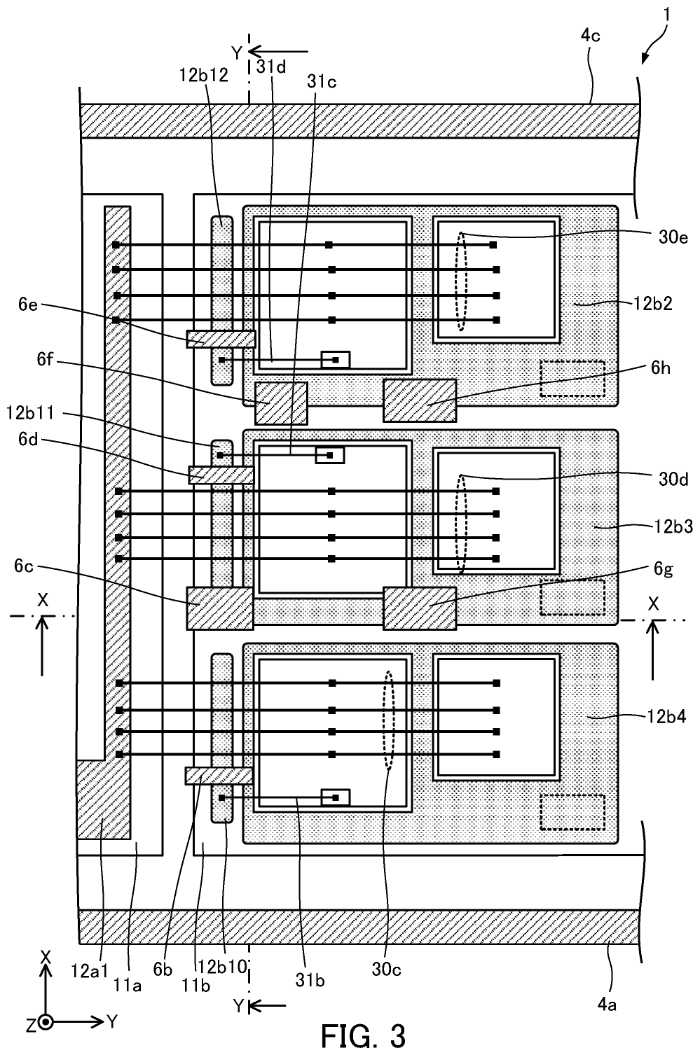

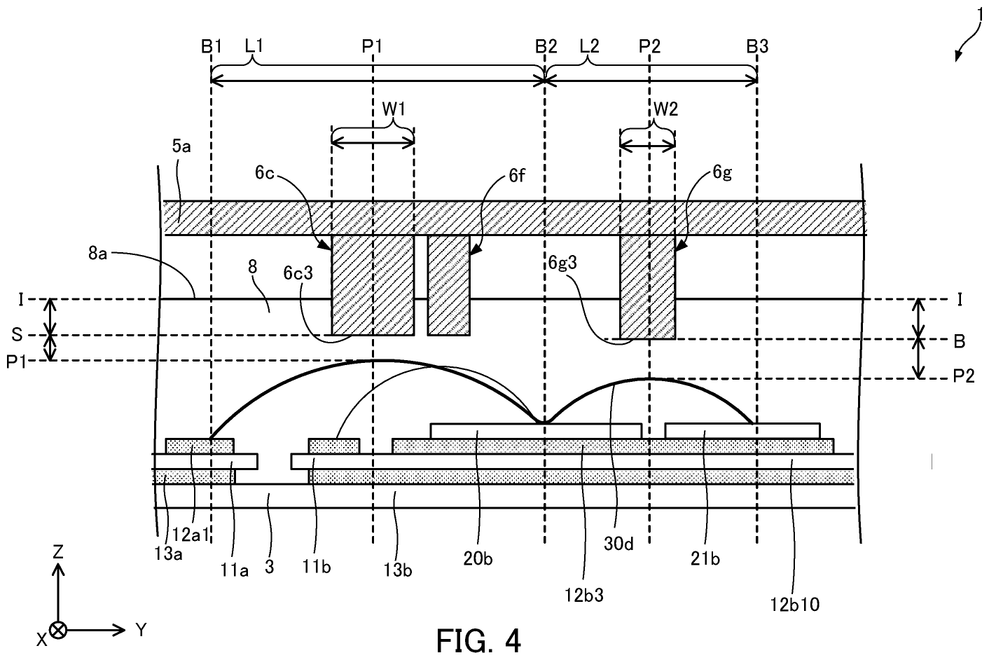

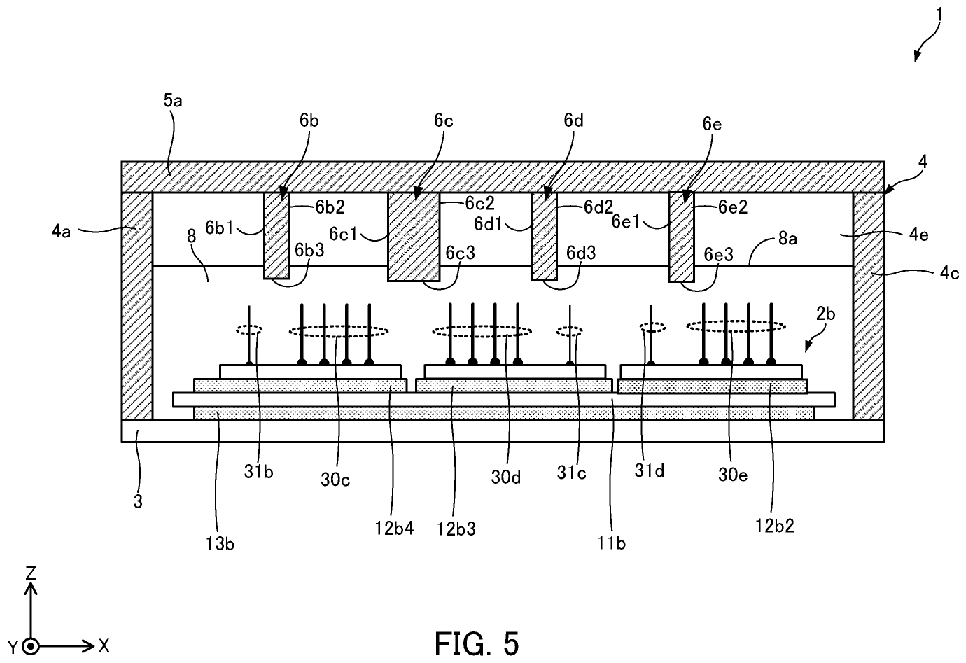

The following describes the buffering members 6 in detail with reference to drawings. The buffering members 6b to 6h inside a broken-line region B of FIG. 2 will first be described with reference to FIGS. 3 to 5. FIG. 3 is a plan view of a main part (buffering members extending in the ±Y directions) of the power conversion device according to the first embodiment. FIGS. 4 and 5 are sectional views of the main part (buffering members extending in the ±Y directions) of the power conversion device according to the first embodiment. In this connection, FIG. 3 is an enlarged view of the main part including the buffering members 6b to 6h. FIG. 4 is a sectional view taken along a dot-dashed line X-X of FIG. 3, and FIG. 5 is a sectional view taken along a dot-dashed line Y-Y of FIG. 3. In FIG. 4, a broken line I indicates the height of the sealing surface 8a of the sealing material 8, broken lines S and B indicate the heights of the buffering bottom surfaces (bottom ends) of the buffering members, and the positions of peak points P1 and P2 indicated by broken lines indicate the heights of peak points of the wires 30d. In addition, broken lines B1 to B3 indicate the bonding points of the wires 30d.

The buffering members 6b to 6h illustrated in FIG. 3 each have a flat plate shape and extend in a first direction in plan view. In this connection, the first direction here is a direction parallel to the ±Y directions. These buffering members 6b to 6h each have buffering surfaces parallel to the long sidewalls 4a and 4c and a buffering bottom surface (bottom end). More specifically, the buffering surfaces are perpendicular to the front surfaces of the insulated circuit substrates 10a and 10b. In addition, the buffering bottom surfaces of the buffering members 6b to 6h are located under the sealing surface 8a of the sealing material 8 and above the wires 30d, and 30e and wires 31b, 31c, and 31d (their peak points) in side view.

For example, the buffering members 6c and 6g are arranged in a line in the ±Y directions in plan view. The buffering members 6c and 6g are provided between the wires 30c and the wires 30d extending in the ±Y directions in plan view. That is, the buffering members 6c and 6g are approximately parallel to the wires 30c and 30d. The buffering members 6c and 6g are preferably provided approximately at the center in the ±X directions of the gap between the wires 30c and the wires 30d (so that the buffering surfaces of each buffering member 6c and 6g have equal distances from the wires 30c and the wires 30d). In addition, the widths (in the ±Y directions) of the buffering members 6c and 6g are widths W1 and W2, respectively, as illustrated in FIG. 4. The centers of the widths W1 and W2 (in the ±Y directions) of the buffering members 6c and 6g face the peak points P1 and P2 of the wires 30d, respectively, in side view. In this connection, the width W1 is at least 10% of the distance L1 between the connection points of the wires 30d to the wiring board 12a1 and the semiconductor chip 20b. The width W2 is at least 10% of the distance L2 between the connection points of the wires 30d to the semiconductor chips 20b and 21b. In addition, as described earlier, the buffering bottom surfaces 6c3 and 6g3 of the buffering members 6c and 6g are located under the sealing surface 8a of the sealing material 8 and above the peak points P1 and P2 of the wires 30d. Therefore, in side view, there are gaps in a vertical direction (Z direction) of the power conversion device 1 between the buffering bottom surface 6c3 of the buffering member 6c and the peak point P1 of the wires 30d and between the buffering bottom surface 6g3 of the buffering member 6g and the peak point P2 of the wires 30d. In this connection, the portions of the buffering members 6c and 6g facing the peak points P1 and P2 of the wires 30d are not limited to the centers of the widths W1 and W2 (in the ±Y directions) of the buffering members 6c and 6g, provided that the buffering members 6c and 6g face the peak points P1 and P2 of the wires in side view.

The buffering members 6b, 6d, and 6e are each provided along the ±Y directions in plan view, as well. The buffering members 6b, 6d, and 6e are provided between the wire 31b and the wires 30c, between the wires 30d and the wire 31c, and between the wire 31d and the wires 30e, respectively. These wires 31b, 30c, 30d, 31c, 31d, and 30e extend in the ±Y directions. That is, the buffering members 6b, 6d, and 6e are approximately parallel to the long sidewalls 4a and 4c. As illustrated in FIG. 5, the buffering members 6b, 6d, and 6e are preferably provided approximately at the centers in the ±X directions of the gaps between the wire 31b and the wires 30c, between the wires 30d and the wire 31c, and between the wire 31d and the wires 30e, respectively (so that the buffering surfaces 6b1 and 6b2 of the buffering member 6b have equal distances from the wire 31b and the wires 30c, the buffering surfaces 6d1 and 6d2 of the buffering member 6d have equal distances from the wires 30d and the wire 31c, and the buffering surfaces 6e1 and 6e2 of the buffering member 6e have equal distances from the wire 31d and the wires 30e).

In addition, as with the buffering members 6c and 6g, the centers of the widths (in the ±Y directions) of the buffering members 6b, 6d, and 6e face peak points of the wires 30c, 30d, and 30e, respectively, in side view. In addition, the widths of the buffering members 6b, 6d, and 6e are at least 10% of the distances between the connection points of the wires 30c, 30d, and 30e to the wiring board 12a1 and the main electrodes of the semiconductor chips 21b, respectively. In side view, there are gaps between the buffering bottom surfaces 6b3, 6d3, and 6e3 of the buffering members 6b, 6d, and 6e and the peak points of the wires 30c, 30d, and 30e, respectively. In addition, the portions of the buffering members 6b, 6d, and 6e facing the peak points of the wires 30c, 30d, and 30e are not limited to the centers of the widths (in the ±Y directions) of the buffering members 6b, 6d, and 6e, provided that the buffering members 6b, 6d, and 6e face the peak points of the wires 30c, 30d, and 30e in side view.

In this connection, main current flows through the wires 30c, 30d, and 30e. On the other hand, control current flows through the wires 31b, 31c, and 31d. Therefore, more current flows through the wires 30c, 30d, and 30e than through the wires 31b, 31c, and 31d, and the wires 30c, 30d, and 30e generate higher heat than the wires 31b, 31c, and 31d. The buffering members 6b, 6d, and 6e are provided to correspond to the peak points of the wires 30c, 30d, and 30e that generate such high heat.

In addition, as described earlier, the buffering bottom surfaces 6b3, 6d3, and 6e3 of the buffering members 6b, 6d, and 6e are located under the sealing surface 8a of the sealing material 8 and above the peak points of the wires 30c, and 30e. Therefore, in side view, there are gaps between the buffering bottom surface 6b3, 6d3, and 6e3 of the buffering members 6b, 6d, and 6e and the peak points of the wires 30c, 30d, and 30e, respectively.

The buffering members 6f and 6h are each provided along the ±Y directions in plan view as well. The buffering member 6f is provided between the wire 31d and the wire 31c that extend in the ±Y directions. The buffering member 6h is provided between the wires 30d and the wires 30e that extend in the ±Y directions. That is, the buffering members 6f and 6h are approximately parallel to the long sidewalls 4a and 4c.

The buffering member 6f is preferably provided approximately at the center in the ±X directions of the gap between the wire 31d and the wire 31c (so that the buffering surfaces of the buffering member 6f have equal distances from the wire 31d and the wire 31c). The buffering member 6h is preferably provided approximately at the center in the ±X directions of the gap between the wires 30d and the wires 30e (so that the buffering surfaces of the buffering member 6h have equal distances from the wires 30d and the wires 30e).

In addition, as with the buffering members 6c and 6g, the centers of the widths (in the ±Y directions) of the buffering members 6f and 6h face peak points of the wires 31c and 31d and the wires 30d and 30e, respectively, in side view. In addition, the width of the buffering member 6f is at least 10% of the distance between the connection points of each wire 31c and 31d to the control electrode of the corresponding semiconductor chip and the corresponding wiring board 12b11 or 12b12. The width of the buffering member 6h is at least 10% of the distance between the connection points of each wire 30d and 30e to the main electrodes of the corresponding semiconductor chips 20b and 21b. In this connection, the portions of the buffering members 6f and 6h facing the peak points of the wires 31c and 31d and the wires 30d and 30e are not limited to the centers of the widths (in the ±Y directions) of the buffering members 6f and 6h, provided that the buffering members 6f and 6h face the peak points of the wires 31c and 31d and the wires 30d and 30e in side view.

In addition, as described earlier, the buffering bottom surfaces of the buffering members 6f and 6h are located under the sealing surface 8a of the sealing material 8 and above the peak points of the wires 31c and 31d and wires 30d and 30e. Therefore, in side view, there are gaps between the buffering bottom surface of the buffering member 6f and the peak points of the wires 31c and 31d and between the buffering bottom surface of the buffering member 6h and the peak points of the wires 30d and 30e.

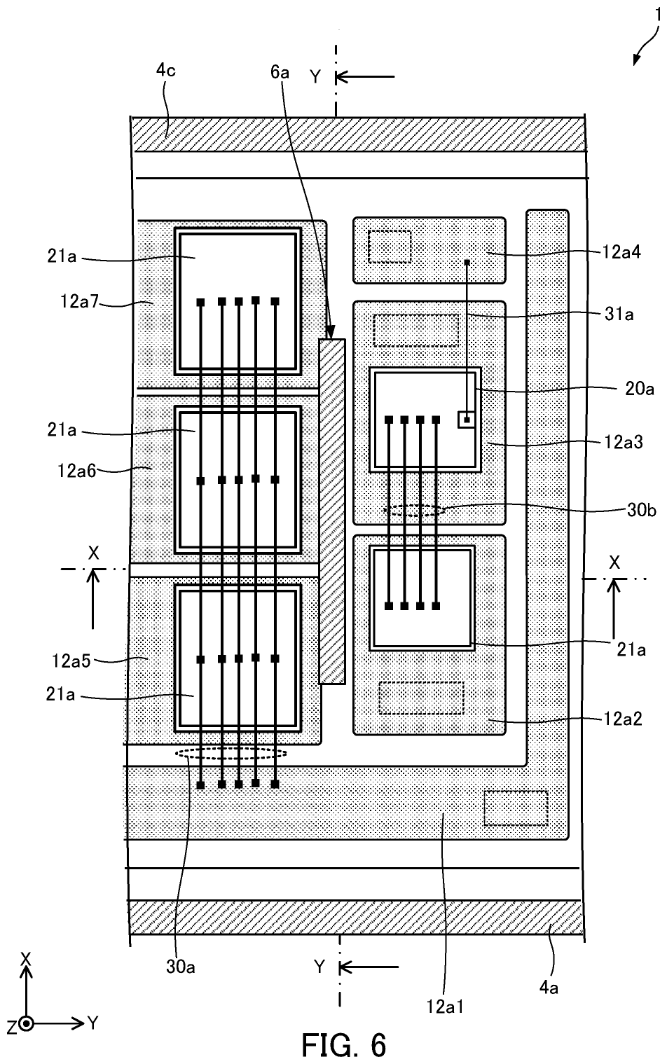

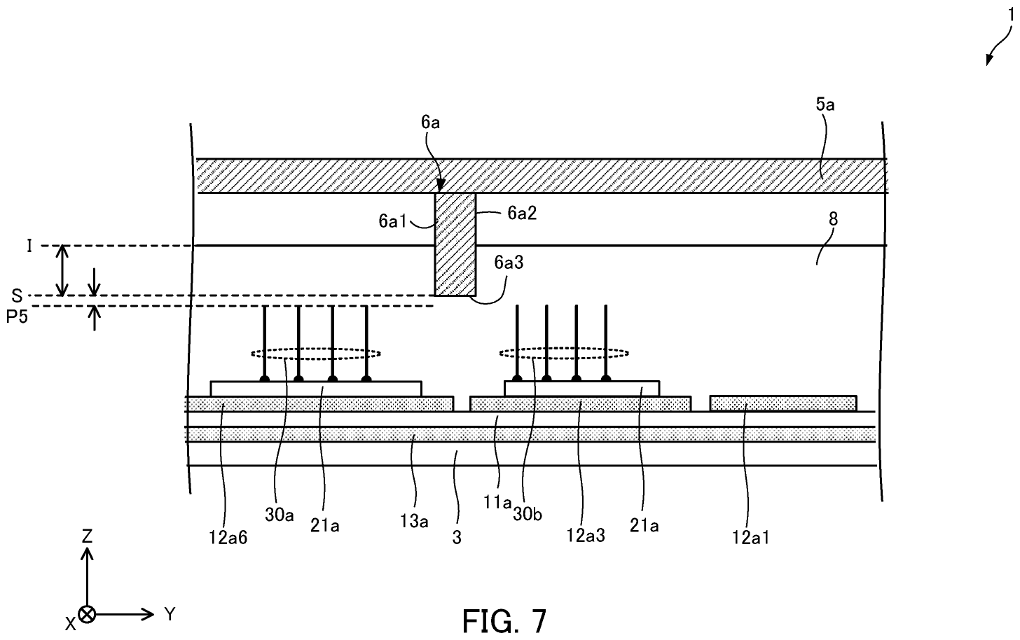

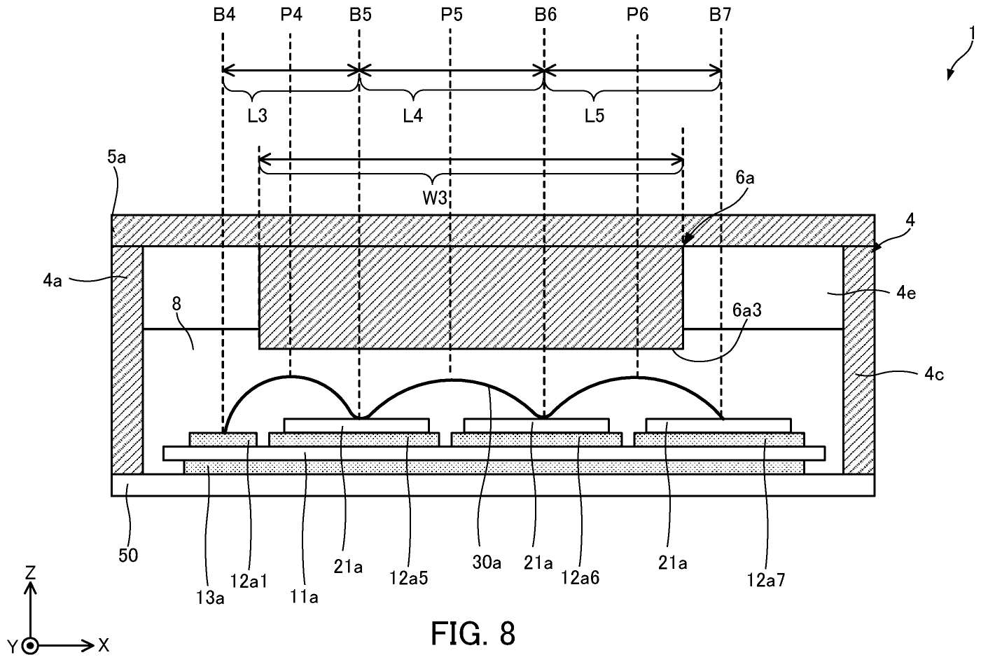

The following describes the buffering member 6a provided in a broken-line region A of FIG. 2, with reference to FIGS. 6 to 8. FIG. 6 is a plan view of a main part (a buffering member extending in the ±X directions) of the power conversion device according to the first embodiment. FIGS. 7 and 8 are sectional views of the main part (the buffering member extending in the ±X directions) of the power conversion device according to the first embodiment. In this connection, FIG. 6 is an enlarged view of the main part including the buffering member 6a. FIG. 7 is a sectional view taken along a dot-dashed line X-X of FIG. 6, whereas FIG. 8 is a sectional view taken along a dot-dashed line Y-Y of FIG. 6. In FIG. 7, a broken line I indicates the height of the sealing surface 8a of the sealing material 8, a broken line S indicates the height of the buffering bottom surface 6a3 of the buffering member 6a, and the positions of peak points P5 indicated by a broken line indicate the heights of the peak points of the wires 30a.

The buffering member 6a illustrated in FIG. 6 extends in a first direction in plan view. In this connection, the first direction here is a direction parallel to the ±X directions. This buffering member 6a is provided along the ±X directions to form a straight line in plan view. The buffering member 6a is provided between the wires 30a and the wires 30b that extend in the ±X directions in plan view. That is, the buffering member 6a is approximately parallel to the wires 30a and 30b. The buffering member 6a is preferably provided approximately at the center in the ±Y directions of the gap between the wires 30a and the wires 30b (so that the buffering surfaces 6a1 and 6a2 of the buffering member 6a have equal distances from the wires 30a and the wires 30b).

The buffering member 6a has a width W3 (in the ±X directions), as illustrated in FIG. 8. The width W3 of the buffering member 6a is set such that the buffering member 6a covers the peak points P4 to P6 of the wires 30a in side view. The buffering member 6a also covers the peak points of the wires in side view, although it is not illustrated. In addition, the buffering bottom surface 6a3 of the buffering member 6a is located under the sealing surface 8a of the sealing material 8 and above the peak points P4 and P6 of the wires 30a. Therefore, there is a gap between the buffering bottom surface 6a3 of the buffering member 6a and the peak points p4 to p6 of the wires (and the peak points of the wires 30b) in side view.

In this connection, as in the case illustrated in FIGS. 3 to 5, buffering members may be provided so as to respectively face the peak points P4 to P6 of the wires 30a in side view, in place of the buffering member 6a. In this case, the widths in the ±X directions of the buffering members may be at least 10% of the distances L3 to L5 between the connection points of each wire 30a.

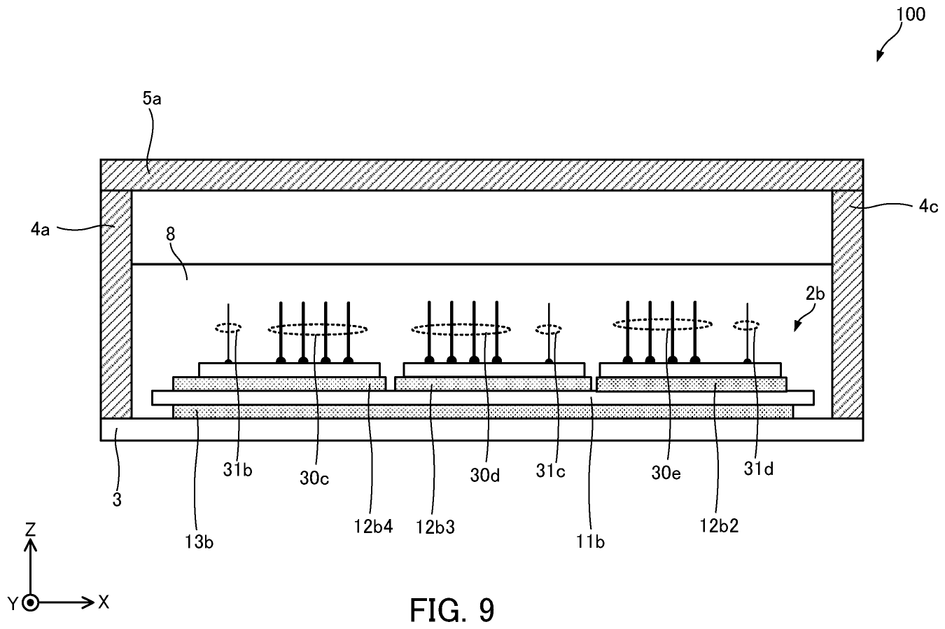

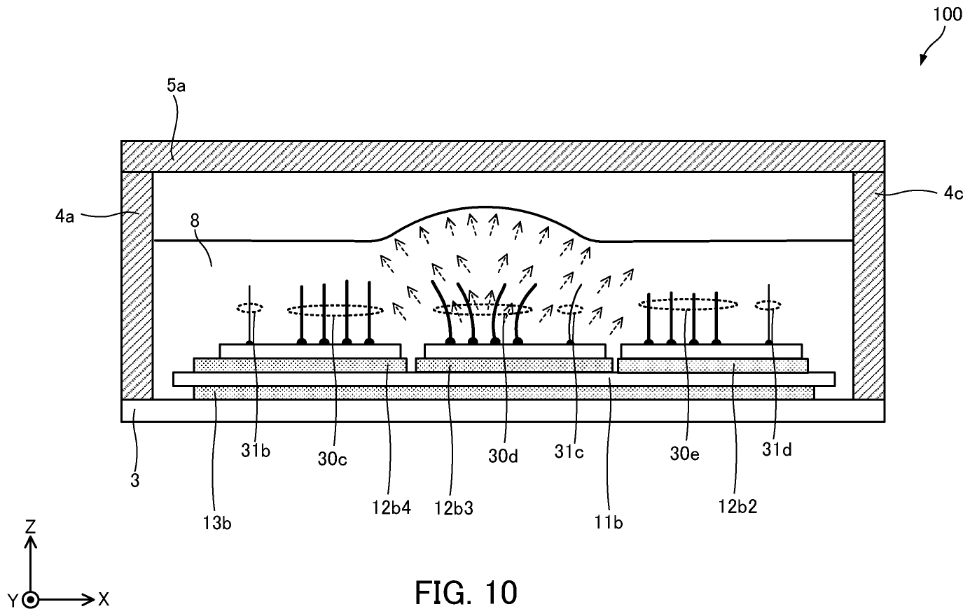

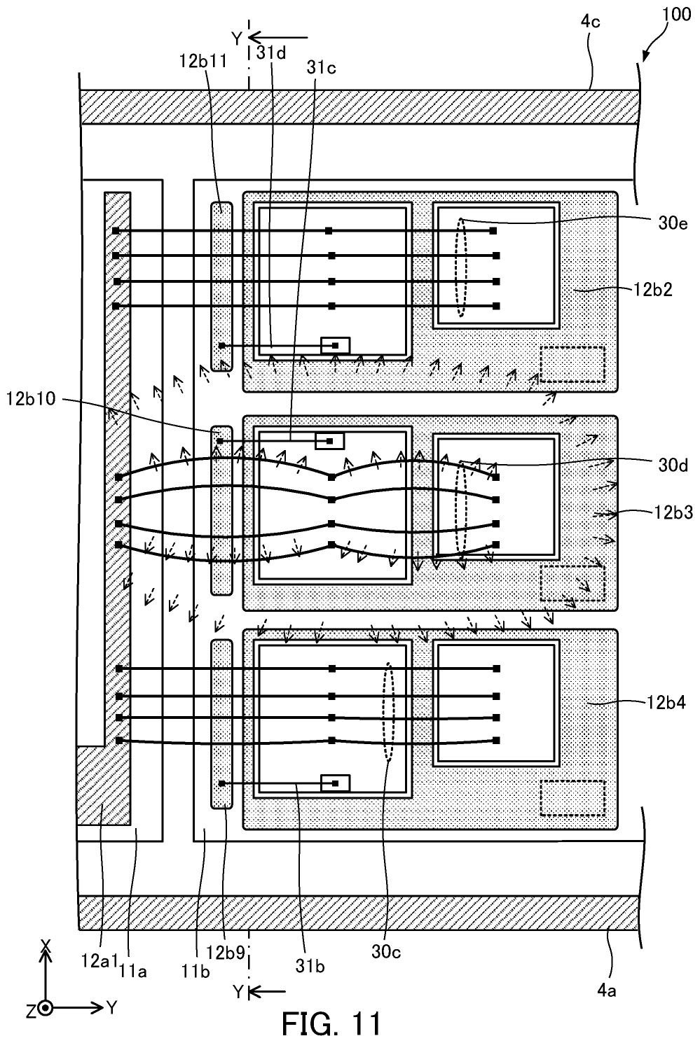

The following describes a power conversion device 100 of a reference example. The power conversion device 100 of the reference example is a device in which the buffering members 6 have been removed from the power conversion device 1 of the first embodiment. This power conversion device 100 will be described with reference to FIGS. 9 to 11. FIG. 9 is a sectional view of a main part of the power conversion device according to the reference example. FIG. 10 is a sectional view of a main part of the power conversion device (during expansion) according to the reference example. FIG. 11 is a plan view of the main part of the power conversion device (during expansion) according to the reference example. In this connection, FIG. 9 corresponds to FIG. 5, and FIG. 11 corresponds to FIG. 3.

It is obvious that, while the power conversion device 100 does not drive, no change occurs in the sealing material 8, and wires 30c, 30d, and 30e are perpendicular to the front surface of an insulated circuit substrate 10b and extend in the ±Y directions, as illustrated in FIG. 9.

The following describes the case where the power conversion device 100 drives, and for example, current flows through the wires 30d, which then generate heat. In this case, the heat from the wires 30d heats a sealing material 8 around the wires 30d. Therefore, the sealing material 8 around the wires 30d expands. More specifically, the sealing material 8 around the wires 30d expands so as to extend isotropically, as illustrated in FIGS. 10 and 11. The extension of the sealing material 8 causes the wires 30d to stretch outward with their connection points to semiconductor chips 21b and 20b and a wiring board 12a1 as fulcrum points. More specifically, the curved peak points of the wires 30d connecting to the semiconductor chips 21b and 20b and wiring board 12a1 are likely to receive stress caused by the expansion of the sealing material 8. Therefore, the peak points of the wires 30d moves tilted, and thus the wires 30d as a whole are tilted isotropically with their connection points to the semiconductor chips 21b and 20b and wiring board 12a1 as fulcrum points. A wire 30d tilted in the −X direction may get in contact with a wire 30c. In addition, a wire 30d tilted in the +X direction may get in contact with a wire 31c. Similarly, the wire 31c tilted due to the extension of the sealing material 8 may get in contact with a wire 30e. Especially, when the wires 30d and 30c having different electrodes contact each other, insulation breakdown occurs. If this happens, the power conversion device 100 fails, which in turn reduces the reliability of the power conversion device 100.

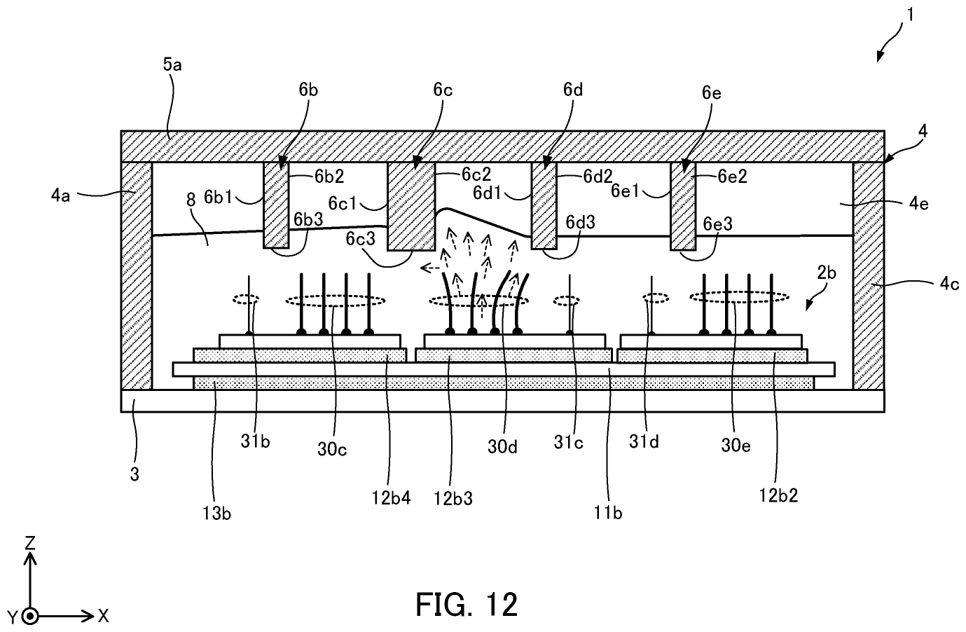

The case where the power conversion device 1 with buffering members drives will be described with reference to FIG. 12. FIG. 12 is a sectional view of a main part (buffering members extending in the ±Y directions) of the power conversion device (during expansion) according to the first embodiment. In this connection, FIG. 12 illustrates the driving state of the power conversion device 1 of FIG. 5.

The following describes the case where the power conversion device 1 drives and the wires 30d generate heat, as in the case where the above-described power conversion device 100 drives. As described above, the sealing material 8 around the wires 30d expand due to the heat from the wires 30d. The power conversion device 1 is provided with the buffering member 6c between the wires 30c and the wires 30d. The sealing material 8 around the wires 30d is a viscoelastic material such as a silicone gel, and expands so as to extend along the buffering surface 6c2 of the buffering member 6c, as illustrated in FIG. 12. That is, the expansion-induced extension (in the −X direction) of the sealing material 8 is restricted by the buffering member 6c. When the expansion-induced extension of the sealing material 8 is restricted, the outward stretching of the wires 30d in the −X direction, especially from the buffering member 6c, is restricted accordingly. That is, the outward stretching of the wires 30d due to the expansion of the sealing material 8 caused by the heat generated by the wires 30d is restricted, which prevents the contact between the wires 30d and having different electrodes. As a result, insulation breakdown is prevented, and a reduction in the reliability of the power conversion device 1 is prevented accordingly. Note that the extension of the sealing material 8 in the +X direction from the buffering member 6d is restricted by the buffering member 6d, although it is not illustrated in FIG. 12. Accordingly, the outward stretching of the wires 30d in the +X direction from the buffering member 6d is restricted as well.

In addition, the bottom ends of the buffering members 6b to 6e are located above the wires 30c to 30e and wires 31b to 31d. Therefore, when the power conversion device 1 is assembled or operates, there is no risk of the buffering members 6b to 6e contacting the wires 30c to 30e and wires 31b to 31d to thereby damage the wires 30c to 30e and 31b to 31d. Since there is no risk of such contact, high positional accuracy is not needed in the assembly, which makes it possible to reduce the assembly manufacturing cost.

The above-described power conversion device 1 includes the semiconductor units 2a and 2b, the case 4, and the sealing material 8. The semiconductor units 2a and 2b include the wires 30a to 30k that each connect between the main electrodes of semiconductor chips, between the main electrodes of the semiconductor chips and the wiring boards, or between the wiring boards and that extend away from these and are curved at their peak points. The case 4 has a frame shape and defines the housing space 4e to accommodates therein the semiconductor units 2a and 2b. The sealing material 8 fills the housing space 4e and has the sealing surface 8a located above the peak points of the wires 30a to 30k included in the semiconductor units 2a and 2b. In addition, the power conversion device 1 includes the buffering members 6 that each extend in a predetermined direction in plan view and that have bottom ends located above the peak points of the wires 30a to 30k and under the sealing surface 8a in side view. When the power conversion device 1 drives, and for example, current flows through the wires 30d, which then generate heat, the expansion-induced extension of the sealing material 8 around the wires 30d caused by the heat from the wires is buffered (restricted) by the buffering members 6. Since the expansion-induced extension of the sealing material 8 is restricted, the outward stretching of the wires 30d is restricted by the buffering members 6 as well, which prevents the contact between the wires 30d and 30c having different electrodes. As a result, insulation breakdown is prevented, and a reduction in the reliability in the power conversion device 1 is prevented accordingly. In addition, it is possible to reduce the distance between the wires 30c and the wires 30d and thus to reduce the size of the power conversion device 1. In addition, there is no risk that the buffering members 6 contact and damage the wires 30d. Therefore, there is no need to change the design of the power conversion device 1 in order to introduce the buffering members 6. This increases the degree of freedom in design and reduces the assembly manufacturing cost.

The buffering members 6 each may be provided to extend in a predetermined direction in plan view and to have a buffering bottom surface located above the peak points of the wires 30a to 30k and under the sealing surface 8a in side view. The buffering members 6 may be located at least on the sides of the wires 30a to 30k in plan view. As described earlier, the peak points of the wires 30a to 30k are likely to receive stress caused by the expansion of the sealing material 8. Therefore, the buffering members 6 are preferably provided so that the central portions of their buffering bottom surfaces respectively face the peak points of the wires 30a to 30k in side view. However, if the buffering members 6 are too narrow in width (parallel to the wiring directions of the corresponding wires to 30k), the effect of buffering the expansion of the sealing material 8 becomes less. To provide a sufficient buffering effect, the widths of the buffering members 6 need to be at least 10% of the distance between connection points of the corresponding wires 30a to 30k.

In this connection, wires having a buffering member 6 therebetween do not need to face each other. The buffering member 6 may be arranged so as to buffer the stress placed on one wire by the expansion of the sealing material 8 due to heat generated by the other wire.

In addition, the buffering members 6 are designed to buffer the expansion-induced extension of the heated sealing material 8. Therefore, a buffering member 6 may be arranged between a wire and a conductive member. For example, the conductive member is an electrode, a lead frame, or a busbar. In this case, since the expansion-induced extension of the sealing material 8 is restricted, the outward stretching of the wire is suppressed by the buffering member 6 as well, which prevents the contact between the wire and the conductive member that have different electrodes.

### Second Embodiment

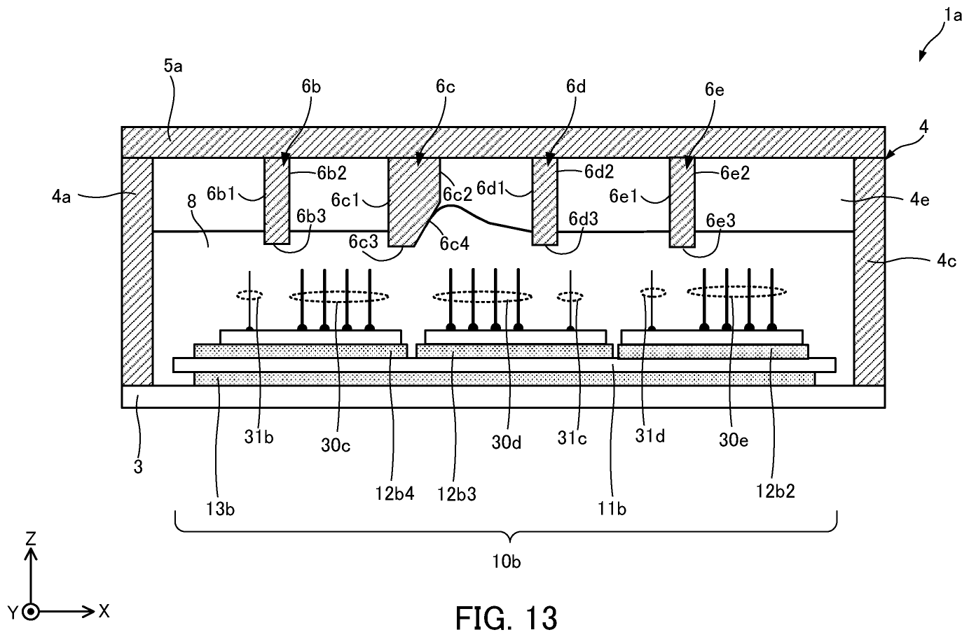

In a second embodiment, the power conversion device 1 of the first embodiment is modified such that the buffering bottom surface of a buffering member 6 has a tapered edge. This case will be described with reference to FIG. 13. FIG. 13 is a sectional view of a main part (buffering members extending in the ±Y directions) of the power conversion device (during expansion) according to the second embodiment. In this connection, FIG. 13 corresponds to FIG. 12. The power conversion device 1a of the second embodiment has the same configuration as the power conversion device 1 of the first embodiment except the buffering member 6.

The buffering surface 6c2 of the buffering member 6c included in the power conversion device 1a of the second embodiment has a tapered portion 6c4 that faces the insulated circuit substrate 10b. This tapered portion 6c4 is formed throughout the width in the ±Y directions of the buffering member 6c. In this connection, the inclination angle of the tapered portion 6c4 with respect to the buffering surface 6c2 is in the range of 5° to 40°, inclusive, for example.

The buffering member 6c includes the tapered portion 6c4. For example, the expansion of the sealing material 8 caused when the wires 30d generates heat is captured by the tapered portion 6c4, so that the sealing material 8 expands along the surface of the tapered portion 6c4. Therefore, the extension (in the ±X directions) of the sealing material 8 is restricted. Since the expansion-induced extension of the sealing material 8 is restricted, the wires 30d are more unlikely to stretch outward than the case of the first embodiment. This prevents the contact between the wires 30d and 30c having different electrodes. As a result, insulation breakdown is prevented, and a reduction in the reliability of the power conversion device 1a is prevented accordingly.

(Variation 2-1)

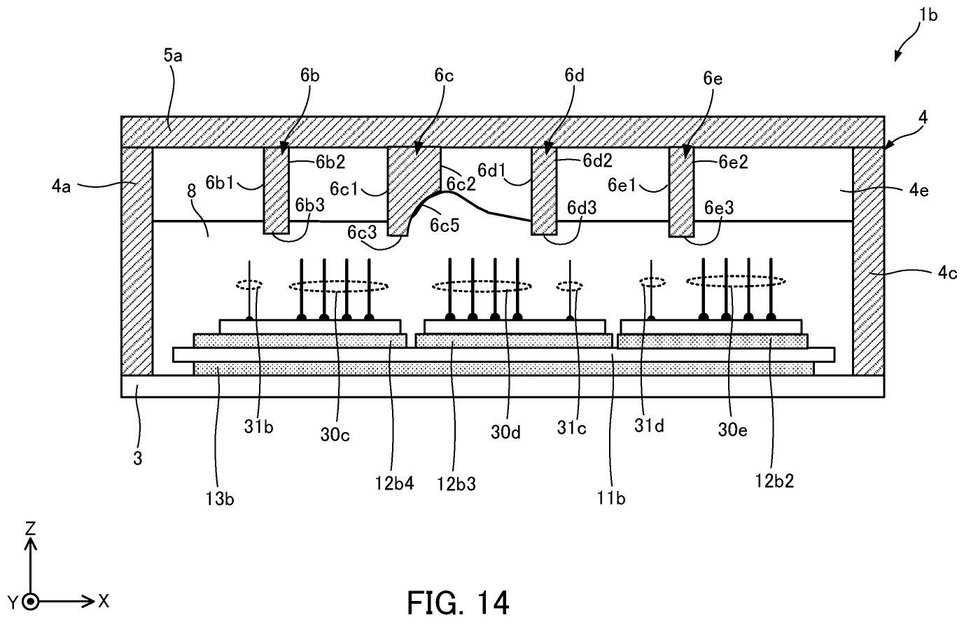

A power conversion device 1b of variation 2-1 will be described with reference to FIG. 14. FIG. 14 is a sectional view of a main part (buffering members extending in the ±Y directions) of a power conversion device (during expansion) according to the second embodiment (variation 2-1). The power conversion device 1b has a concave portion 6c5 in the buffering surface 6c2 of the buffering member 6c. The power conversion device 1b has the same configuration as the power conversion device 1 except the formation of the concave portion 6c5.

The concave portion 6c5 of the buffering member 6c has a curved surface (R-surface) recessed toward the inside of the buffering member 6c. The concave portion 6c5 is formed throughout the width in the ±Y directions of the buffering member 6c. The buffering member 6c having the concave portion 6c5 is able to reliably capture the expansion of the sealing material 8 caused by the heat of the wires 30d, as compared with the power conversion device 1a. Accordingly, the stretching (in the ±X directions) of the wires 30d is suppressed reliably, as compared with the first embodiment. This prevents the contact between the wires 30d and 30c. As a result, insulation breakdown is prevented, and a reduction in the reliability of the power conversion device 1b is prevented accordingly.

(Variation 2-2)

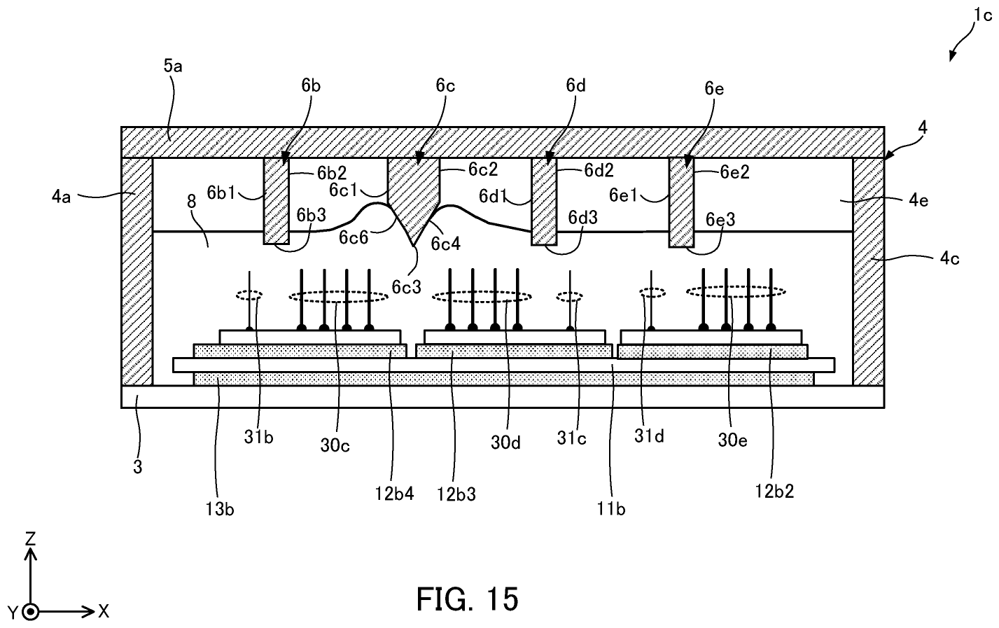

A power conversion device 1c of variation 2-2 will be described with reference to FIG. 15. FIG. 15 is a sectional view of a main part (buffering members extending in the ±Y directions) of a power conversion device (during expansion) according to the second embodiment (variation 2-2). The power conversion device 1c has a tapered portion 6c4 in the buffering sur face 6c2 of the buffering member 6c, as with the power conversion device 1a, and also has a tapered portion 6c6 in the buffering surface 6c1 opposite to the tapered portion 6c4. The tapered portions 6c4 and 6c6 are each formed throughout the width in the ±Y directions of the buffering member 6c. That is, the tapered portions 6c4 and 6c6 are symmetrically formed in the buffering member 6c. The power conversion device 1c has the same configuration as the power conversion device 1 except the formation of the tapered portions 6c4 and 6c6.

The buffering member 6c has both the tapered portion 6c4 and the tapered portion 6c6 opposite to the tapered portion 6c4. The expansion of the sealing material 8 caused when at least either the wires 30d or the wires 30c generate heat is captured by the tapered portions 6c4 and 6c6, so that the sealing material 8 expands along the surfaces of the tapered portions 6c4 and 6c6. The expansion-induced extension (in the ±X directions) of the sealing material 8 is restricted. Therefore, as compared with the first embodiment, the outward stretching of the wires 30c is suppressed by the buffering member 6c when the wires 30c generate heat and the outward stretching of the wires 30d is suppressed by the buffering member 6c when the wires 30d generate heat, which prevent the contact between the wires 30c and 30d. As a result, insulation breakdown is prevented, and a reduction in the reliability of the power conversion device 1c is prevented accordingly. Therefore, the formation of the tapered portions 6c4 and 6c6 in the buffering member 6c makes it possible to deal with the expansion of the sealing material 8 caused by the heat from any of the wires 30c and 30d.

In addition, each tapered portion 6c4 and 6c6 may be formed in a concave shape in the buffering member 6c, as with the concave portion 6c5. By doing so, the wires 30c and 30d rarely receive stress caused by the expansion of the sealing material 8, which prevents short circuiting of the wires 30c and and thus prevents a reduction in the reliability of the power conversion device 1c.

### Third Embodiment

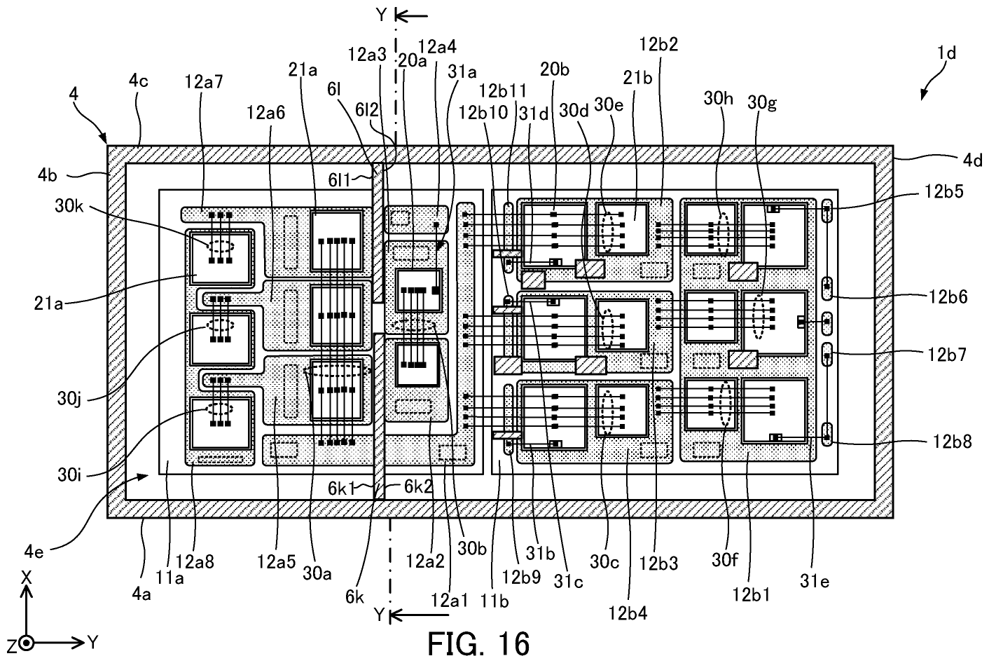

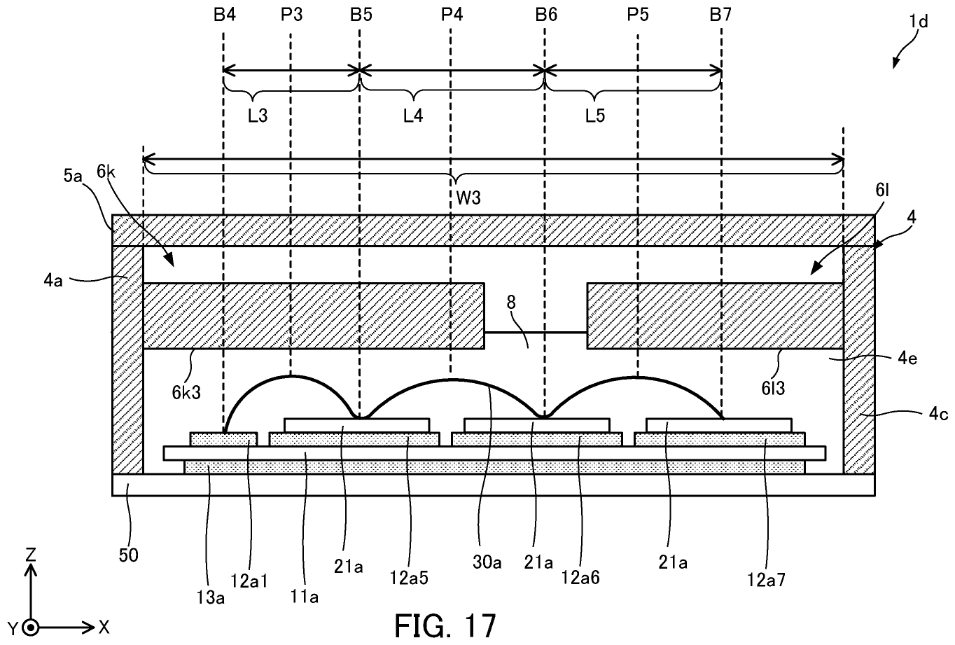

In a power conversion device 1d of a third embodiment, buffering members are formed on a case 4, not on the rear surface of a lid. This power conversion device 1d will be described with reference to FIGS. 16 and 17. FIG. 16 is a plan view of the power conversion device according to the third embodiment, and FIG. 17 is a sectional view of a main part (buffering members extending in the ±X directions) of the power conversion device according to the third embodiment. In this connection, FIG. 17 is a sectional view taken along a dot-dashed line Y-Y of FIG. 16.

The power conversion device 1d includes buffering members 6k and 6l, in place of the buffering member 6a of the power conversion device 1. The buffering members 6k and 6l each have a flat plate shape. The buffering member 6k has a pair of buffering surfaces 6k1 and 6k2 and a buffering bottom surface 6k3, and the buffering member 6l has a pair of buffering surfaces 611 and 612 and a buffering bottom surface 613. The buffering members 6k and 6l are formed in line (in the ±X directions) on the inner walls of the long sidewalls 4a and 4c. In addition, the buffering members 6k and 6l extend from the long sidewalls 4a and 4c toward the center of the housing space 4e in plan view. That is, the buffering members 6k and 6l extend in the first direction (±X directions) in which the semiconductor chips 21a are separate from each other.

The buffering member 6k extends from the long sidewall 4a beyond the peak point P4 of the wires 30a in the +X direction in side view. The buffering member 6l extends from the long sidewall 4c beyond the peak point P5 of the wires 30a in the −X direction in side view. In addition, the buffering bottom surfaces 6k3 and 613 of the buffering members 6k and 6l are located over the peak points P3, P4, and P5 of the wires 30a in side view. In this connection, the side portion (on the −X side) of the buffering member 6k may be located above the peak points P3 and P4 of the wires 30a in side view, and may contact the top end of the long sidewall 4a. Similarly, the side portion (on the +X side) of the buffering member 6l may be located above the peak points P4 and P5 of the wires 30a in side view, and may contact the top end of the long sidewall 4c.

In addition, the buffering members 6k and 6l may be formed as a continuous flat plate, not as separate plates. In this case, the continuous flat plate is formed so as to cross between the long sidewalls 4a and 4c. Alternatively, the buffering members 6k and 6l may be formed so as to extend up to above the peak points P3 and P5 of the wires 30a, respectively, in side view. In this case, an additional buffering member may be formed on the rear surface of the lid 5 so as to extend down to above the peak point P4 of the wires 30a. The buffering members 6k and 6l formed on the long sidewalls 4a and 4c and the buffering member formed on the rear surface of the lid 5 may be appropriately selected so as to correspond to the peak points P3 to P5 of the wires 30a.

For example, the sealing material 8 expands along the buffering members 6k and 6l due to heat of at least either the wires 30a or the wires 30b. Therefore, the expansion of the sealing material 8 in the ±Y directions due to the heating wires and 30b is restricted. The outward stretching of the wires is restricted by the buffering members 6k and 6l when the wires 30a generate heat, and the outward stretching of the wires is restricted by the buffering member 6k and 6l when the wires 30b generate heat. Therefore, the contact between the wires 30a and 30b is prevented. As a result, insulation breakdown is prevented, and a reduction in the reliability of the power conversion device 1d is prevented accordingly.

In addition, a tapered portion or concave portion, as in the second embodiment, may be formed in the ±X directions in each buffering surface 6k1 and 6k2 of the buffering member 6k on the side thereof where the buffering bottom surface 6k3 is located, as illustrated in FIG. 15 of variation 2-2. Similarly, a tapered portion or concave portion may be formed in each buffering surface 611 and 612 of the buffering member 6l as well. This case as well provides the same effects as variation 2-2.

According to the disclosed technique, while a power conversion device operates, the contact between wires is prevented, and short circuiting is prevented, and a reduction in the long-term reliability of the power conversion device is prevented accordingly.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A power conversion device, comprising:
a first conductive unit including a first conductive part having a first front surface and a second conductive part having a second front surface, the second conductive part being separate from the first conductive part in a first direction parallel to the first and second front surfaces;
a first wire connecting the first front surface to the second front surface, the first wire extending away from the first front surface and the second front surface and being curved at a first peak point thereof;
a second conductive unit located on a side of the first conductive unit, the second conductive unit including a third conductive part having a third front surface, and a fourth conductive part having a fourth front surface, the fourth conductive part being separate from the third conductive part in the first direction;
a second wire connecting the third front surface to the fourth front surface, the second wire extending away from the third front surface and the fourth front surface and being curved at a second peak point thereof;
a case forming a frame to define a housing space to accommodate therein the first conductive unit and the second conductive unit;
a sealing material sealing the housing space and having a sealing surface located above the first peak point and the second peak point; and
a buffering member extending in the first direction in a plan view of the power conversion device, the buffering member having a bottom end that, in a side view of the power conversion device, is located above the first peak point and the second peak point and under the sealing surface.

2. The power conversion device according to claim 1, wherein the buffering member is located between the first wire and the second wire in the plan view.

3. The power conversion device according to claim 2, wherein the buffering member has a flat plate shape with a first buffering surface facing the first conductive unit and a second buffering surface facing the second conductive unit.

4. The power conversion device according to claim 3, wherein the bottom end of the buffering member faces the first peak point of the first wire in the side view.

5. The power conversion device according to claim 4, wherein a width in the first direction of the bottom end of the buffering member is at least 10% of a distance between connection points of the first wire to the first front surface and the second front surface.

6. The power conversion device according to claim 3, wherein the first buffering surface is perpendicular to the first front surface and the second front surface.

7. The power conversion device according to claim 3, wherein the first buffering surface includes a portion inclined to face the first front surface and the second front surface.

8. The power conversion device according to claim 3, wherein the first buffering surface includes a portion with a curved surface recessed toward an inside of the buffering member.

9. The power conversion device according to claim 3, wherein the second buffering surface includes a portion inclined to face the third front surface and the fourth front surface.

10. The power conversion device according to claim 3, wherein the second buffering surface includes a portion with a curved surface recessed toward an inside of the buffering member.

11. The power conversion device according to claim 1, wherein the first wire is provided in plurality, and each of the plurality of first wires connects the first front surface to the second front surface.

12. The power conversion device according to claim 1, wherein the second wire is provided in plurality, and each of the plurality of second wires connects the third front surface to the fourth front surface.

13. The power conversion device according to claim 1, further comprising a lid covering an opening of the case, wherein the buffering member is provided on a surface of the lid that faces the sealing surface.

14. The power conversion device according to claim 1, wherein the buffering member is provided on an inner wall of the case and extends in the first direction.
